(19) United States
(12) Patent Application Publication
(10) Pub. No.: US 2020/0168468 A1
(43) Pub. Date: May 28, 2020

(54) ETCHING METHOD AND SUBSTRATE PROCESSING APPARATUS

(71) Applicant: Tokyo Electron Limited, Tokyo (JP)

(72) Inventors: Takayuki ISHII, Miyagi (JP); Taichi OKANO, Miyagi (JP); Sho OIKAWA, Miyagi (JP)

(21) Appl. No.: 16/693,609

(22) Filed: Nov. 25, 2019

(30) Foreign Application Priority Data
Nov. 26, 2018 (JP) 2018-220603

(51) Int. Cl. H01L 21/3065; H01L 21/263; H01L 21/308; H01L 21/67

(52) U.S. Cl. CPC H01L 21/30655; H01L 21/67069; H01L 21/3081; H01L 21/2633

(57) ABSTRACT

An etching method is provided. In the method, a substrate including an etching target film, a hard mask containing silicon and a patterned resist is provided. A protective film is formed on a surface of the substrate by generating a first plasma from one of a first gas containing carbon, fluorine and a dilute gas, and a second gas containing carbon, hydrogen and the dilute gas. The hard mask is etched by generating a second plasma from a third gas after performing the step of forming the protective film.

### CROSS-REFERENCE TO RELATED APPLICATION

The present application is based on and claims priority to Japanese Priority Application No. 2018-220603 filed on Nov. 26, 2018, the entire contents of which are hereby incorporated herein by reference.

### BACKGROUND OF THE INVENTION

### 1. Field of the Invention

The present disclosure relates to an etching method and a substrate processing apparatus.

### 2. Description of the Related Art

Japanese Patent Application Publication No. 2010-41028 discloses a method of processing a wafer in which an amorphous carbon film, a SiON film, an anti-reflection film, and a photoresist layer are sequentially deposited on a silicon substrate, and the photoresist layer has an opening that exposes a portion of the anti-reflection film. Japanese Patent Application Publication No. 2010-41028 proposes depositing a film on the side wall of the opening of the photoresist film to reduce the opening width of the opening to a predetermined width.

Japanese Patent Application Publication No. 2006-253245 describes a technique that expands a pattern width of a mask layer by depositing a plasma reaction product on sidewalls of the mask layer, etches a lower layer, embeds a mask material in the etched lower layer, performs etching while leaving the mask material as a mask, and forms a fine pattern.

### SUMMARY OF THE INVENTION

In one embodiment, the present disclosure provides a technique that can increase a controllable range of an opening width of a target film.

According to an embodiment of the present disclosure, there is provided an etching method. In the method, a substrate including an etching target film, a hard mask containing silicon and a patterned resist is provided. A protective film is formed on a surface of the substrate by generating a first plasma from one of a first gas containing carbon, fluorine and a dilute gas, and a second gas containing carbon, hydrogen and the dilute gas. The hard mask is etched by generating a second plasma from a third gas after performing the step of forming the protective film.

Additional objects and advantages of the embodiments are set forth in part in the description which follows, and in part will become obvious from the description, or may be learned by practice of the disclosure. The objects and advantages of the disclosure will be realized and attained by means of the elements and combinations particularly pointed out in the appended claims. It is to be understood that both the foregoing general description and the following detailed description are exemplary and explanatory and are not restrictive of the disclosure as claimed.

### BRIEF DESCRIPTION OF THE DRAWINGS

FIG. 1 is a diagram illustrating an example of a substrate processing apparatus according to an embodiment;

FIGS. 2A to 2C are diagrams illustrating an example of a conventional etching process for a three-layer structure;

FIG. 3 is a diagram illustrating an example of an etching method for a three-layer structure according to an embodiment;

FIGS. 4A to 4D are diagrams illustrating an example of an etching process for a three-layer structure according to an embodiment;

FIG. 5 is a diagram illustrating an example of an effect of an etching method according to an embodiment;

FIG. 6 is a flowchart illustrating an example of an etching method according to a first modification of an embodiment; and

FIG. 7 is a flowchart showing an example of an etching method according to a second modification of an embodiment.

### DETAILED DESCRIPTION OF THE PREFERRED EMBODIMENTS

Hereinafter, embodiments for carrying out the present disclosure will be described with reference to the drawings. In each drawing, the same reference numerals are used for the same components and overlapping descriptions may be omitted.

[Overall Configuration of Substrate Processing Apparatus]

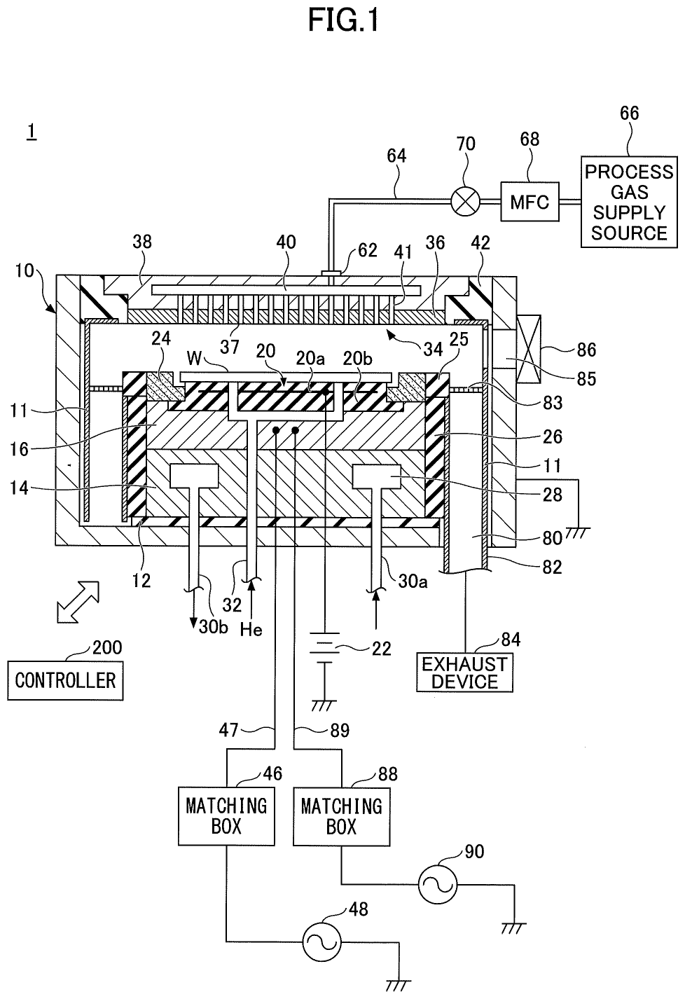

FIG. 1 is a diagram illustrating an example of a substrate processing apparatus 1 according to an embodiment. The substrate processing apparatus 1 according to the present exemplary embodiment is a parallel plate capacitively coupled plasma processing apparatus, and includes a cylindrical process chamber 10, for example, made of aluminum with an anodized surface. The process chamber 10 is grounded.

At the bottom of the process chamber 10, a cylindrical support platform 14 is disposed through an insulating plate 12 made of ceramics and the like. A stage 16, for example, made of aluminum, is disposed on the support platform 14. The stage 16 constitutes a lower electrode, and a wafer W is placed on an electrostatic chuck 20 disposed on the stage 16.

The electrostatic chuck 20 attracts and holds the wafer W by electrostatic force. The electrostatic chuck 20 has a structure in which an electrode 20a made of a conductive film is sandwiched between insulating layers 20b. A DC power source 22 is connected to the electrode 20a, and a wafer W is attracted on and held by the electrostatic chuck 20 by an electrostatic force, such as Coulomb force generated by a DC voltage from the DC power source 22.

A conductive edge ring 24, for example, made of silicon, is disposed on the stage 16 around a periphery of the wafer W. A cylindrical inner wall member 26, such as quartz, is disposed around the outer periphery of the stage 16 and the support platform 14. A ring-shaped insulator ring 25 made of quartz or the like is disposed around the outer peripheral side surface of the edge ring 24.

A refrigerant chamber 28 is disposed inside the support platform 14, for example, on a circle. An externally provided chiller unit supplies a refrigerant, such as cooling water, at a predetermined temperature through pipes 30a and 30b to the refrigerant chamber 28, and a processing temperature of the wafer W on the stage 16 is controlled by the refrigerant temperature. In addition, a heat transfer gas, for example, He gas, is supplied from a heat transfer gas supply mechanism through a gas supply line 32 to a location between the top surface of the electrostatic chuck 20 and the back surface of the wafer W.

An upper electrode 34 is disposed facing and above the stage 16. Between the top electrode 34 and the bottom electrode is a plasma processing space. The upper electrode 34 forms a face that faces the wafer W on the stage 16 and contacts with the plasma processing space, that is, an opposing face.

The top electrode 34 is supported on the ceiling of the process chamber 10 via an insulative shielding member 42. The upper electrode 34 includes an electrode plate 36 that forms an opposite face to the stage 16 and has a number of gas discharge holes 37, and an electrode support 38 made of a conductive material such as aluminum that is anodized on the surface of the electrode plate 36. The electrode support 38 detachably supports the electrode plate 36. The electrode plate 36 is preferably made of silicon or SiC. The electrode support 38 includes thereinside a gas diffusion chamber 40, through which a number of gas flowing holes 41 in communication with the gas discharge holes 37 extends downward.

The electrode support 38 includes a gas inlet 62 that guides a process gas to the gas diffusion chamber 40 formed therein. A gas supply line 64 is connected to the gas inlet 62, and a treatment gas supply source 66 is connected to the gas supply line 64. The gas supply line 64 includes a mass flow controller (MFC) 68 and an on-off valve 70 from the upstream side where the process gas supply source 66 is located. The process gas is then supplied from the process gas supply source 66 through the gas supply line 64 to the gas diffusion chamber 40, and is discharged into the plasma processing space in a shower-like manner from the gas flowing holes 41 and the gas discharge holes 37. In this manner, the upper electrode 34 serves as a showerhead for supplying a process gas. The process gas supply source 66 is an example of a gas supplier for supplying an etching gas or another gas.

A first radio frequency power source 48 is connected to the stage 16 via a power feeding rod 47 and a matching box 46. The first radio frequency power source 48 supplies an HF power to the stage 16, which is radio frequency power for plasma generation. The frequency of the HF may be 40 MHz to 60 MHz. The matching box 46 matches internal impedance and load impedance of the first radio frequency power source 48. A filter may be connected to the stage 16 for transmitting a predetermined high frequency power to the ground. The HF power supplied from the first radio frequency power source 48 may be supplied to the upper electrode 34.

A second radio frequency power source 90 is connected to the stage 16 via a power source rod 89 and a matching box 88. The second radio frequency power source 90 supplies an LF power to the stage 16, which is radio frequency power for attracting ions. This draws ions to the wafer W on the stage 16. The second radio frequency power source 90 outputs a radio frequency power at a frequency in a range of 2 MHz to 13.56 MHz. The matching box 88 matches internal impedance and load impedance of the second radio frequency power source 90.

The bottom of the process chamber 10 includes an exhaust port 80 to which an exhaust device 84 is connected via an exhaust pipe 82. The exhaust device 84 includes a vacuum pump, such as a turbomolecular pump, which can decrease the pressure in the process chamber 10 to a desired degree of vacuum. The side wall of the process chamber 10 includes a wafer transfer port 85 that a gate valve 86 can open and close. A deposition shield 11 is detachably disposed along the inner wall of the process chamber 10 to prevent deposits of by-products formed during etching or the like from adhering to the process chamber 10. That is, the deposition shield 11 constitutes the wall of the process chamber 10. The deposition shield 11 is also provided on the outer circumference of the inner wall member 26 and a part of the ceiling thereof. A baffle plate 83 is disposed between the deposition shield 11 on the wall side of the process chamber 10 at the bottom of the process chamber 10 and the deposition shield 11 on the inner wall member 26 side. The deposition shield 11 and the baffle plate 83 may be made of an aluminum material coated with a ceramic such as Y₂O₃.

When the etching process is performed in a substrate processing apparatus of such a configuration, first, the gate valve 86 is opened, and a wafer W is carried into the process chamber 10 via the transfer port 85 and placed on the stage 16. A gas for plasma process, such as etching, is supplied to the gas diffusion chamber 40 at a predetermined flow rate from the process gas supply 66 and is supplied into the process chamber 10 via the gas flowing holes 41 and the gas discharge holes 37. The exhaust device 84 also evacuates the process chamber 10 and sets the pressure to a pressure defined by process conditions.

While the gas is introduced into the process chamber 10 in this manner, HF power is supplied from the first radio frequency power source 48 to the stage 16. The second radio frequency power source 90 also supplies LF power to the stage 16. The DC power source 22A applies a DC voltage to the electrode 20a, thereby holding the wafer W on the stage 16.

A Process gas discharged from the gas discharge holes 37 of the upper electrode 34 is dissociated and ionized primarily by HF power, thereby generating plasma. Also, by supplying the LF power to the stage 16, the ions in the plasma are primarily controlled. The surface to be processed of the wafer W is etched by radicals and ions in the plasma.

The substrate processing apparatus 1 includes a controller 200 for controlling operation of the entire apparatus. The controller 200 performs a plasma process, such as etching, according to a recipe stored in a memory, such as a ROM (Read Only Memory) and a RAM (Random Access Memory). The recipe may define a process time, a pressure (gas exhaust), a high frequency power, a voltage, and various gas flows, which are control information of the apparatus to satisfy process conditions. The recipe may also define a temperature in the process chamber 10 (the temperature of the upper electrode, the temperature of the side wall of the process chamber 10, the wafer W temperature, the temperature of the electrostatic chuck and the like), a temperature of the refrigerant output from the chiller and the like. A recipe indicating the procedures and conditions of these processes may be stored on a hard disk or a semiconductor memory. The recipe may be set in a predetermined position and be read out in a portable computer-readable storage medium such as a CD-ROM, a DVD, and the like.

[Conventional Three-Layer Structured Etching Process]

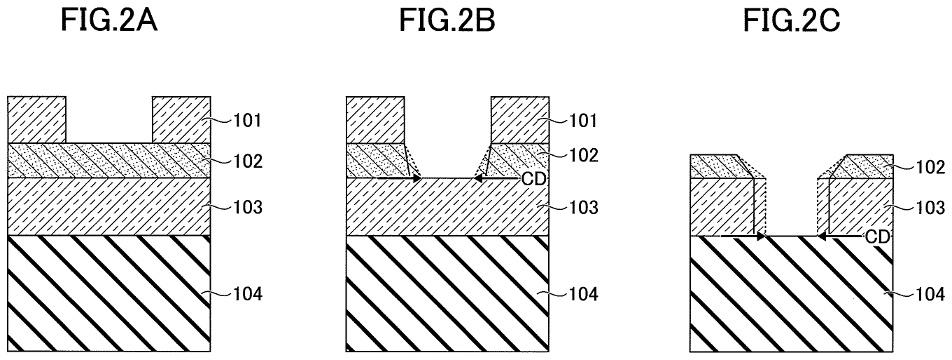

For a three-layer structured stacked film having a three-layer structure in which an etching target film, an intermediate film, and a hard mask are sequentially stacked, there is a process of etching a pattern of a photoresist film on the hard mask. In an example of FIG. 2A, an SiO₂ film (silicon oxide film) 104, which is an example of an etching target film, is formed on the wafer, and an organic film 103, which is an example of an intermediate layer, is formed thereon. Then, as an example of a hard mask, a DARC (Dielectric Anti-Reflective Coating) film 102 is formed, on which a pattern of a photoresist film 101 is formed.

For the pattern of the photoresist film 101, the opening width after etching the target film is sometimes required to be decreased by several nm to several tens of nm. Conventional etching methods have controlled the flow ratio of CF₄ gas to CHF₃ gas while etching the DARC film 102 with CF₄ gas and CHF₃ gas or with CF₄ gas, CHF₃ gas and O₂ gas to control the amount of deposits deposited on the DARC film 102. However, it is possible to use CH₂F₂, C₄F₈, CH₄, and C₄F₆. For example, increasing CHF₃ gas relative to the CF₄ gas increases the amount of deposition deposited on the sidewalls. Thus, as illustrated in FIG. 2B, control was performed such as reducing the opening width (also referred to as a “CD” (critical dimension)) of the DARC film 102. Thereafter, as illustrated in FIG. 2C, a method was used to reduce the CD of the SiO₂ film 104 by etching the organic film 103 using the DARC film 102 as a mask, and etching the SiO₂ film 104, which is the etching target film, using the organic film 103 as a mask.

However, in the conventional etching method, supplying CHF₃ gas at a too much flow rate will cause an etching failure. That is, deposits deposited on the bottom of the etched hole of the DARC film 102 increase, which causes an etching stop and disables the etching. Therefore, the reduction of the CD by controlling the CHF₃ gas flow rate has a limit, and sometimes the CD cannot be decreased to the required value.

[Etching Process of a Three-Layer Structure According to One Embodiment]

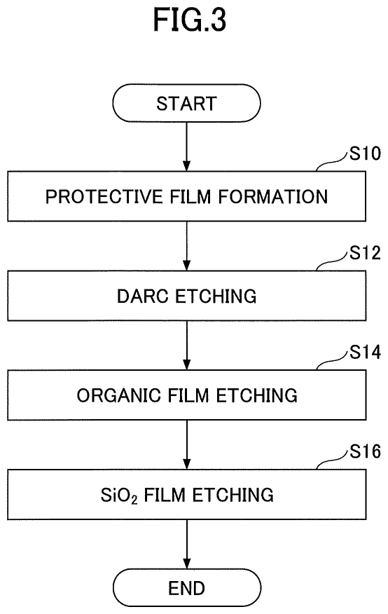

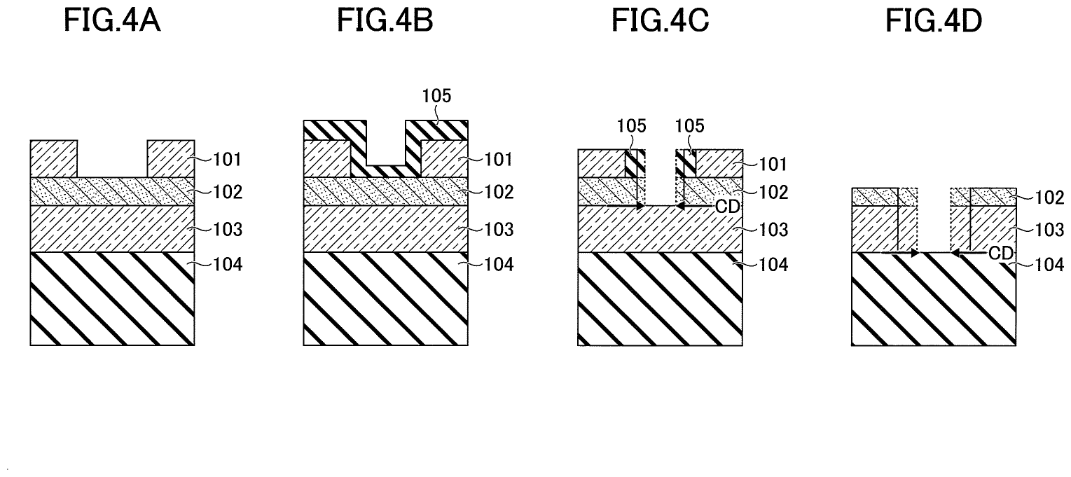

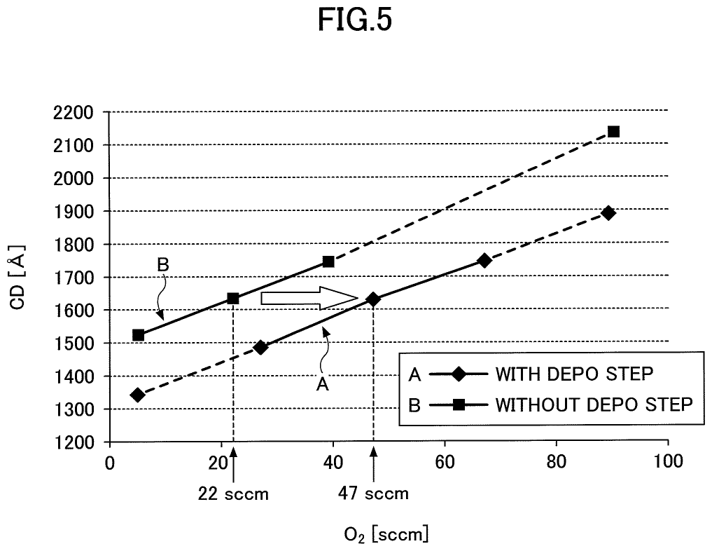

Therefore, one embodiment proposes an etching method that can expand a controllable range of the CD of the target film. Particularly in this etching method, the range can be extended in a controllable direction to reduce the CD of the target film. Hereinafter, the etching method according to one embodiment will be described with reference to FIGS. 3 to 5. FIG. 3 is a flowchart illustrating an example of an etching method of a three-layer structure according to an embodiment. FIGS. 4A to 4D are diagrams illustrating an example of an etching process of a three-layer structure according to an embodiment. FIG. 5 is a diagram for explaining an example of an effect of an etching method according to an embodiment.

FIG. 4A illustrates an example of a stacked film etched by an etching method according to an embodiment. The structure of the stacked film is the same as that of the three-layer structured film illustrated in FIG. 2A. The hard mask is a silicon-containing film, including, for example, SiO₂, SiN, SiC, SiCN. An example of a photoresist film 101 is an organic film.

A wafer W having the stacked film formed by one of the examples is carried into the substrate processing apparatus 1, and the controller 200 controls an etching method according to the present embodiment by executing a program indicating the procedure of the etching method according to the present embodiment. The program is read into the memory of the controller 200 and used for the control.

[Deposition Process]

In the etching method according to the present embodiment, as illustrated in a flowchart of FIG. 3, first, in Step S10, a protective film 105 is formed for the stacked film having the three-layer structure illustrated in FIG. 4A. FIG. 4B illustrates a state of a protective film 105 formed for the stacked film having the three-layer structure. This reduces the opening width of the pattern of the photoresist film 101. Process conditions of the present process are as follows.

[Process Conditions]

Pressure: 50 mT to 100 mT HF Power: 300W

LF Power: 0 W

Gas Species: H₂, C₄F₆, Ar

In this process, C₄F₆ gas of a deposition gas becomes a CF-based deposit in plasma and is deposited on the top, sides and bottom (on the DARC film 102) of the pattern of the photoresist film 101, thereby forming a protective film 105.

The present process is an example of a first process in which a gas containing C, F, and a dilute gas or a gas containing C, H, and a dilute gas is introduced as a first gas to form a protective film before etching the hard mask.

The first gas introduced in the present process is not limited to H₂, C₄F₆, and Ar gases, but may also be a gas containing C, F, and a dilution gas, or a gas containing C, H, and a dilution gas. That is, the first gas may or may not contain H₂ gas. The gas including C and F contained in the first gas or the gas including C and H contained in the first gas may include at least one of C₄F₆, C₄F₈, CH₄ and CH₂F₂ gases.

Also, the dilution gas contained in the first gas may be not limited to Ar, but may be at least one of Ar gas, He gas, and CO gas.

[DARC Membrane Etching Process]

A DARC film 102 is then etched into a pattern complying with the protective film 105 on the photoresist film 101 in step S12 of FIG. 3. FIG. 4C illustrates an etched DARC film 102. Due to the protective film 105, the CD of the pattern in the DARC film 102 can be decreased in size. The etching conditions in the present process are as follows.

[Etching Conditions]

DC Voltage (top electrode applied): 450 V

Gas Species: CF₄, CHF₃, O₂

In the present process, the DARC film 102 is etched, and the organic film 103 is exposed. In this case, the protective film 105 formed on the bottom of the pattern of the photoresist film 101 can be etched together with the DARC film 102 under the etching conditions.

This process is an example of a second process in which a second gas is introduced into the process chamber 10 and the hard mask is etched after the first process is performed. The second gas may be a gas containing C and F or a gas containing C and H. The second gas may or may not contain an O₂ gas. For example, the second gas may be CF₄ gas, CHF₃ gas and O₂ gas, or may be CF₄ gas and CHF₃ gas. The second gas may use CH₂F₂ gas instead of CHF₃ gas.

Returning to FIG. 3, in step S14, the organic film 103 is etched, and in step S16, the SiO₂ film 104 is etched and the present process ends.

O₂ gas may be used in the etching of the organic film 103, but is not limited thereto. The etching of the SiO₂ film 104 may use, but is not limited to CF₄, C₄F₈, and Ar gases.

As discussed above, the etching method according to one embodiment performs the step of reducing the CD by the protective film 105 formed by depositing a deposit on the photoresist film 101 before etching the DARC film 102. The DARC film 102 and the protective film 105 are then etched in etchable conditions. Thus, as illustrated in FIG. 4D, the organic film 103 is etched using the DARC film 102 on which the CD is more decreased than the conventional one as a mask. Then, the SiO₂ film 104 is etched using the organic film 103 on which the CD is decreased as a mask.

According to the etching method according to the present embodiment, a first process of depositing a deposit on the photoresist film 101 is added prior to etching the DARC film 102. Thus, a CD controllable range of the etching target film can be more expanded than conventional methods. Therefore, the CD of the SiO₂ film 104, which is the final etching target film, can be decreased.

Referring to FIG. 5, the reason why the CD controllable range of the etching target film can be expanded including the CD decreasing side by adding the first process will be described. The horizontal axis of FIG. 5 shows a flow rate of O₂ gas, and the vertical axis shows a CD value of an etching target film.

Line A shows an example of a CD value when a flow rate of O₂ gas is variably controlled in a second process (etching process of a DARC film 102) using CF₄, CHF₃, and O₂ gas after performing the first process (deposition process of the protective film 105: deposition step) of the present embodiment.

Line B relates to a conventional method as described above and shows an example of controlling a CD by varying a flow rate of O₂ gas when the etching process of the DARC film 102 is performed using the same gas without performing the first process (depo step) of the present embodiment. Here, a CD value obtained by varying the flow rate of O₂ gas in the etching process of the DARC film 102 is shown. This is an example, and the CD value can be similarly controlled by varying the flow rate of CF₄ gas or CHF₃ gas, which results in the same result.

For example, if the target CD of the opening formed in the DARC film 102 is 1600[Å], the flow rate of O₂ gas corresponding to the target CD can be more increased in the line A of the present embodiment than the flow rate of O₂ of the line B of the conventional method by performing the first process of the present embodiment.

That is, the etching method of the present embodiment had a wider margin than the conventional method even on the side of reducing the flow rate of O₂ gas in the etching process of the DARC film 102. As a result, the CD controllable range of the DARC film 102 was able to be extended to the CD reducing side.

According to the graph of FIG. 5, the line B, which shows the conventional method, have the middle flow rate of 22 sccm in the controllable range of O₂ gas used in the etching process of the DARC film 102. Because the minimum control value of the flow rate of O₂ gas is 5 sccm according to the specification of the gas flow controller, the range of the controllable flow rate of O₂ gas is 22 sccm±17 sccm on the line B, which shows the conventional method. Correspondingly to this, the CD controllable range in the conventional method is 153 nm to 215 nm.

On the other hand, in the line A of the present embodiment, the middle flow rate within the controllable range of O₂ gas used in the etching process of the DARC film 102 is 47 sccm. Because the minimum control value of the flow rate of O₂ gas is 5 sccm, the range of the controllable flow rate of O₂ gas is 47 sccm±42 sccm in the line A of the present embodiment. Correspondingly to this, the range within which the CD can be controlled in the present embodiment is 135 nm to 190 nm.

Thus, in the present embodiment, the lower limit of the controllable range of the CD can be reduced from 153 nm to 135 nm compared to the conventional method. This has a significant effect of reducing the CD value by about 20 nm. This effect has a meaning of enabling a further microfabrication by reducing the CD by about 20 nm in recent years when the required CD value is decreasing.

As discussed above, according to the etching method according to the present embodiment, the first process of forming the protective film 105 is performed prior to etching the DARC film 102. This shifts the middle flow rate within the controllable range of the gas used in the etching process of the DARC film 102 to a greater value and expands the range of controllable flow rates of the gas. This allows the flow rate of the gas while etching the DARC film 102 to be controlled in a greater range and allows a CD that is the opening width of the pattern of the photoresist film 105 to decrease to a required width.

As a result, when the organic film 103 is etched using the DARC film 102 as a mask, and when the SiO₂ film 104 is finally etched using the organic film 103 as a mask, the CD of the SiO2 film 104 can be reduced to the target value.

In this manner, the opening width of the DARC film 102, which is the target film, can be reduced to a CD of the aimed target (for example, 1600 Å±100 to 200 Å). Thus, the CD of the organic film 103, which is the intermediate film, and the CD of the SiO₂ film 104, which is the final etching target film, can be reduced to the target width.

### Modification Examples

### First Modification

In the etching method of the present embodiment, a first process of forming the protective film 105 is performed prior to etching the DARC film 102. On the other hand, in the etching method according to the first modification of the present embodiment, which is described below, the first process of forming the protective film 105 is performed while etching the hard mask.

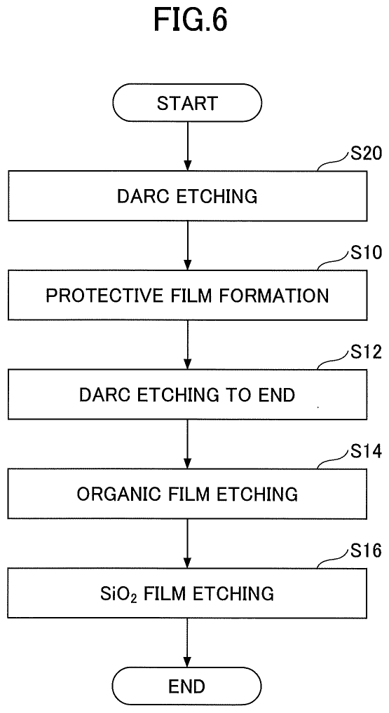

The etching method according to the first modification will be described with reference to FIG. 6. The processes of steps S10 to S16 are the same as those of the etching method according to the present embodiment. The etching method according to the first modification differs from the etching method according to the present embodiment in that step S20 is performed before step S10. That is, after the DARC film 102 is etched, the protective film 105 may be formed, as described in the etching method according to Modification 1. The amount of etching the DARC film 102 may be a degree that is slightly dent or greater than the dent. The DARC film 102 may be etched approximately half.

### Second Modification

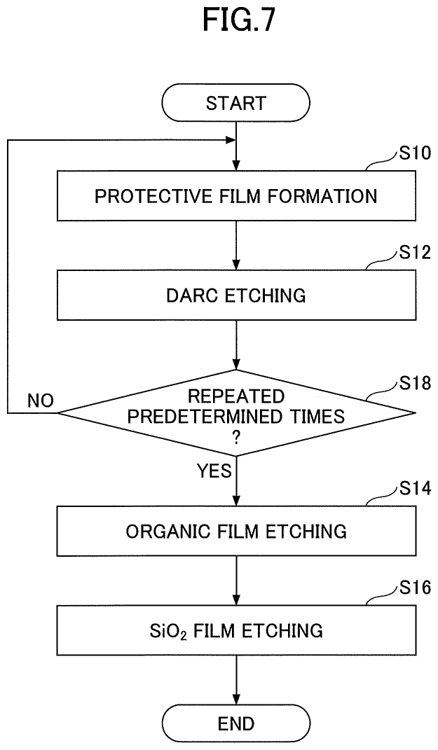

The first process of forming the protective film 105 and the second process of etching the DARC film 102 may be repeated. An etching method according to a second modification will be described with reference to FIG. 7. The processes of steps S10 to S16 are the same as the etching method according to the present embodiment. The etching method according to the second modification differs from the etching method according to the present embodiment in that the first step and the second step shown in steps S10 and S12 are repeated a predetermined number of times. In the second modification, when it is determined that the first step and the second step are repeated one or more times in a predetermined number of times (Step S18), the organic film 103 and the SiO₂ film 104 are etched (Steps S14 and S16).

In the etching method according to the second modification, the first process of forming the protective film 105 is performed a plurality of times by repeating the first process and the second process. This allows the DARC film 102 to be etched while protecting the side walls of the DARC film 102, thereby allowing more accurate control of the CD value of the SiO₂ film 104.

As described above, according to the etching method of the present embodiment and the first and second modifications, it is possible to expand the controllable range of the opening width of the target film.

The etching method according to one embodiment disclosed herein is to be considered exemplary in all respects and not limiting. The above embodiments may be changed and modified in various forms without departing from the appended claims and spirit thereof. The matters described in the above embodiments may take other configurations to the extent not inconsistent, and may be combined to the extent not inconsistent.

Thus, according to the embodiment of the present disclosure, a controllable range of an opening width of a target film can be increased.

The processing apparatus of the present disclosure is applicable to all types of Capacity Coupled Plasma (CCP), Inductively Coupled Plasma (ICP), Radial Line Slot Antenna (RLSA), Electron Cyclotron Resonance Plasma (ECR), and Helicon Wave Plasma (HWP).

The wafer W has been described herein as an example of a substrate. However, the substrate may not be limited thereto, but may be a variety of substrates used in the Liquid Crystal Display (LCD) or the Flat Panel Display (FPD), a CD substrate, a printed circuit board and the like.

All examples recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority or inferiority of the disclosure. Although the embodiments of the present disclosure have been described in detail, it should be understood that various changes, substitutions, and alterations could be made hereto without departing from the spirit and scope of the disclosure.

What is claimed is:

1. An etching method, comprising steps of:
providing a substrate including an etching target film, a hard mask containing silicon and a patterned resist;
forming a protective film on a surface of the substrate by generating a first plasma from one of a first gas containing carbon, fluorine and a dilute gas, and a second gas containing carbon, hydrogen and the dilute gas; and
etching the hard mask by generating a second plasma from a third gas after performing the step of forming the protective film.

2. The etching method as claimed in claim 1, wherein the dilute gas contained in the one of the first gas and the second gas is at least any one of Ar, He and CO.

3. The etching method as claimed in claim 1, wherein the one of the first gas and the second gas contains at least any one of C₄F₆, C₄F₈, CH₄ and CH₂F₂.

4. The etching method as claimed in claim 1, wherein the third gas contains carbon and fluorine, or carbon and hydrogen.

5. The etching method as claimed in claim 1, wherein the step of forming the protective film comprises a step of generating the first plasma by supplying radio frequency power of a frequency of 40 to 60 MHz to the one of the first gas and the second gas.

6. The etching method as claimed in claim 1, wherein the steps of forming the protective film and etching the hard mask are repeated two or more times.

7. The etching method as claimed in claim 1, wherein the step of providing the substrate comprises a step of providing the substrate including an intermediate layer between the etching target film and the hard mask.

8. The etching method as claimed in claim 7, wherein the intermediate layer is made of an organic film.

9. An etching method, comprising:
providing a substrate including an etching target film, a hard mask containing silicon and a patterned resist;
forming a protective film on a surface of the substrate by generating a first plasma from one of a first gas containing carbon, fluorine and a dilute gas, and a second gas containing carbon, hydrogen and the dilute gas while etching the hard mask; and
etching the hard mask by generating a second plasma from a third gas after performing the step of forming the protective film.

10. The etching method as claimed in claim 9, wherein the dilute gas contained in the one of the first gas and the second gas is at least any one of Ar, He and CO.

11. The etching method as claimed in claim 9, wherein the one of the first gas and the second gas contains at least any one of C₄F₆, C₄F₈, CH₄ and CH₂F₂.

12. The etching method as claimed in claim 9, wherein the third gas contains carbon and fluorine, or carbon and hydrogen.

13. The etching method as claimed in claim 9, wherein the step of forming the protective film comprises a step of generating the first plasma by supplying radio frequency power of a frequency of 40 to 60 MHz to the one of the first gas and the second gas.

14. The etching method as claimed in claim 9, wherein the steps of forming the protective film and etching the hard mask are repeated two or more times.

15. The etching method as claimed in claim 9, wherein the step of providing the substrate comprises a step of providing the substrate including an intermediate layer between the etching target film and the hard mask.

16. The etching method as claimed in claim 15, wherein the intermediate layer is made of an organic film.

17. A substrate processing apparatus, comprising:
a process chamber;
a stage disposed in the process chamber to receive a substrate;
a gas supplier configured to supply a gas; and
a controller configured to execute a program to perform the flowing steps, including:
providing a substrate including an etching target film, a hard mask containing silicon and a patterned resist on the stage disposed in the process chamber;
forming a protective film on a surface of the substrate by generating a first plasma from one of a first gas containing carbon, fluorine and a dilute gas, and a second gas containing carbon, hydrogen and the dilute gas supplied from the gas supplier; and
etching the hard mask by generating a second plasma from a third gas supplied from the gas supplier after performing the step of forming the protective film.

18. The substrate processing apparatus as claimed in claim 17, further comprising:
a radio frequency power source configured to supply radio frequency power of a frequency of 40 to 60 MHz to the one of the first gas and the second gas, and the third gas to generate the first plasma and the second plasma.
